(19) United States
(12) Patent Application Publication
(10) Pub. No.: US 2011/0096213 A1
(43) Pub. Date: Apr. 28, 2011

(54) WAFER-SHAPED OPTICAL APPARATUS AND MANUFACTURING METHOD THEREOF, ELECTRONIC ELEMENT WAFER MODULE, SENSOR WAFER MODULE, ELECTRONIC ELEMENT MODULE,SENSOR MODULE, AND ELECTRONIC INFORMATION DEVICE

(75) Inventor: Masahiro Hasegawa, Osaka (JP)

(73) Assignee: SHARP KABUSHIKI KAISHA, Osaka-shi, Osaka (JP)

(21) Appl. No.: 12/736,175

(22) PCT Filed: Mar. 18, 2009
(86) PCT No.: PCT/JP2009/055356

§ 371 Date: Jan. 10, 2011

(30) Foreign Application Priority Data
Mar. 21, 2008 (JP) 2008-074430

(51) Int. Cl. H04N 5/335; H01L 31/0232; G02B 1/10; B32B 3/10; G02B 1/12; B29D 11/00

(52) U.S. Cl. 348/294; 257/432; 359/601; 428/192; 264/1.36; 216/24; 257/E31.128; 348/E05.091

(57) ABSTRACT

A single material is used for an optical member, such as a lens, to obtain high optical accuracy. A glass substrate with a plurality of holes is used as a base material (framework), and overall resin contraction occurred during manufacturing is restrained and a wafer-shaped lens module having a plurality of resin lenses with high dimensional accuracy can be formed. Further, variation in the thickness of the glass substrate is absorbed by lens resin formed on the glass substrate, and the thickness of a flange section can be controlled accurately and variation between resin lenses can also be controlled accurately when layered. Further, a lens portion of the resin lens is made only of a single lens resin, and the refractive index can be maintained even, the designing can be facilitated, and the thickness can be controlled accurately to manufacture a condensing lens with high accuracy.

### TECHNICAL FIELD

The present invention relates to a wafer-shaped optical apparatus comprised of a plurality of lenses for focusing incident light, or a plurality of optical functional elements for directing and reflecting straight output light and refracting and guiding incident light in a predetermined direction, and a method for manufacturing the wafer-shaped optical apparatus; an electronic element wafer module including a plurality of image capturing elements modularized (integrated) therein, the image capturing elements having a plurality of light receiving sections for performing a photoelectric conversion on and capturing an image of image light from a subject, corresponding to respective lenses, or an electronic element wafer module including a plurality of light emitting elements for generating output light and light receiving elements for receiving incident light, corresponding to respective optical functional elements, modularized (integrated) therein; an electronic element module manufactured by simultaneously cutting the electronic element wafer module; a sensor wafer module including a plurality of image capturing elements having a plurality of light receiving sections for performing a photoelectric conversion on and capturing an image of image light from a subject, and lenses for forming an image from incident light on the image capturing elements, modularized (integrated) therein; and an electronic information device, such as a digital camera (e.g., a digital video camera or a digital still camera), an image input camera (e.g., a car-mounted camera), a scanner, a facsimile machine, a television telephone device, a camera-equipped cell phone device and a personal digital assistant (PDA), the electronic information device including a sensor module cut from the sensor wafer module as an image input device, such as a car-mounted camera, used in an image capturing section of the electronic information device, or an electronic information device, such as a pick-up apparatus, including the electronic element module in an information recording and reproducing section thereof.

### BACKGROUND ART

The conventional sensor module of this type, as an electronic element module, is mainly used as a camera module in a camera-equipped cell phone device, a personal digital assistant (PDA), a card camera and the like. The sensor module is provided with a solid-state image capturing chip having an image capturing element as an electronic element, and a holder member with a condensing lens fixed thereto for forming an image from incident light onto the image capturing element, the image capturing element having a plurality of light receiving sections for performing a photoelectric conversion on and capturing an image of image light from a subject, on a mount substrate, such as ceramics and glass-containing epoxy resin. In this case, the solid-state image capturing chip is arranged and wire-bonded on the mount substrate.

In the meantime, lens modules, such as the condensing lens, are used broadly for various types of electronic information devices, such as a cell phone camera module and a laser pick-up apparatus. The lens modules are conventionally manufactured by a method for manufacturing a small number of lenses under a high temperature and pressure using a resin injection molding method.

Reference 1 is a U.S. patent document, which discloses a method for forming a plurality of lens modules simultaneously. FIGS. 19 and 20 are respectively examples of the lens modules. As illustrated in FIG. 19, a lens module 100 is formed such that a plurality of holes 102 are formed in a silicon substrate 101, a spherical glass ball 103 is inserted into each hole 102, the glass ball 103 is fixed with a solder 104 to prevent the glass ball 103 from falling off, and the glass ball 103 is grinded for a predetermined amount from the top to be flattened to form a condensing lens with a spherical lower side.

As illustrated in FIG. 20, in a lens module 200, a lens shape 202 is formed on one side of a glass substrate 201 using a photo-etching method. An etching process is performed with a photoresist on a position of an opposite side surface 203 where an optical axis aligns with the lens shape 202, to transfer a photoresist shape onto the glass substrate 201 to form a lens shape (not shown). As such, a lens substrate is formed.

These examples are all illustrated as a method for forming a plurality of condensing lenses simultaneously on a predetermined wafer-shape.

Reference 1: U.S. Pat. No. 6,049,430

### DISCLOSURE OF THE INVENTION

The above-mentioned conventional structure as illustrated in FIG. 19 uses the spherical glass ball 103. With such a glass ball 103, it is difficult to focus a target point. In order to focus a target point, it is necessary to use a non-spherical glass ball. However, there is no such technique currently existing for mounting a non-spherical glass ball into the hole 102 while controlling the glass ball for securing a desired lens characteristic. Thus, it is not possible to manufacture a non-spherical lens using the subject method. It is also difficult to grind the glass ball 103 equally in such a manner to obtain a desired lens characteristic. Furthermore, although the plurality of holes 102 are formed into the silicon substrate 101 by wet etching such that the opening of the holes is widened, variation arises in the size of the holes 102. Owing to the variation of the size of the holes 102, the vertical position of the glass balls 103 differ from one another. As a result, a final lens thickness varies. When the size of the glass ball 103 is 700 μm and the thickness of the substrate is 500 μm in order to manufacture a condensing lens of 1 mm in thickness, in consideration of a 2% etching variation to be converted into a lens thickness, there will be a 10 μm variation. This will not satisfy such a condition that the variation must be within a few μm required for the lens performance.

In the above-mentioned conventional structure as illustrated in FIG. 20, the glass substrate 201 is used as a part of its lens. The lens has a hybrid structure of a resist (resin) material (lens shape 202) and a glass material (glass substrate 201). The refractive index of the lens changes in the middle of the lens, which causes many design restrictions. Further, in the glass material (glass substrate 201), variation of +/−5% occurs in substrate thickness between substrates. Thus, even if the glass substrate 201 of 100 μm in thickness is used, there will be a total of 10 μm variation in lens thickness, which is not possible to obtain a desired lens characteristic.

The present invention is intended to solve the conventional problem described above. The objective of the present invention is to provide: a wafer-shaped optical apparatus capable of obtaining a high optical accuracy by using a single material for optical parts, such as a lens, and a method for manufacturing the wafer-shaped optical apparatus; an electronic element wafer module using the wafer-shaped optical apparatus therein; a sensor module in which an electronic element using the wafer-shaped optical apparatus therein is a solid-state image capturing element; an individual electronic element module simultaneously cut from the electronic element wafer module; an individual sensor module simultaneously cut from the sensor wafer module; and an electronic information device, such as a camera-equipped cell phone device, including the electronic element module such as the sensor module used as an image input device in an image capturing section.

A wafer-shaped optical apparatus according to the present invention includes: a base material substrate with one or a plurality of holes provided therein; a resin optical element section provided in each hole of the base material substrate; and a flange section provided in a peripheral position of the optical element section on the base material substrate, thereby achieving the objective described above.

Preferably, in a wafer-shaped optical apparatus according to the present invention, the base material substrate is a glass substrate.

Still preferably, in a wafer-shaped optical apparatus according to the present invention, a light shielding film is provided on a surface of the base material substrate.

Still preferably, in a wafer-shaped optical apparatus according to the present invention, the light shielding film has a two layered structure of a light shielding chromium plating and a low reflection chromium plating as a base layer of the light shielding chromium plating.

Still preferably, in a wafer-shaped optical apparatus according to the present invention, the optical element section is any of a lens, a mirror optical element, a waveguide section, a prism or a hologram element.

Still preferably, in a wafer-shaped optical apparatus according to the present invention, the flange section is constituted of at least the base material substrate among the base material substrate and a resin material identical to the optical element section.

Still preferably, in a wafer-shaped optical apparatus according to the present invention, in the flange section, a resin material identical to that of the optical element section is arranged in a film shape on at least one of an upper surface and a lower surface of the base material substrate.

Still preferably, in a wafer-shaped optical apparatus according to the present invention, the flange section is constituted of only the base material substrate.

Still preferably, in a wafer-shaped optical apparatus according to the present invention, the hole is in any shape of a circle, an ellipse, a rectangle, or a polygon.

Still preferably, in a wafer-shaped optical apparatus according to the present invention, a resin material of the optical element section is a thermosetting resin material or a photo-curable resin.

A method for manufacturing a wafer-shaped optical apparatus according to the present invention is provided, with a base material substrate as a framework and a resin optical element section being molded at a hole of the base material substrate, the method including: a hole forming step of forming one or a plurality of holes in the base material substrate; a pressing step of putting an optical element resin and the base material substrate between optical element lower and upper metal molds formed to correspond to the hole, to mold at least the optical element section; and a resin curing step of curing the resin using heat or light, thereby achieving the objective described above.

Preferably, in a method for manufacturing a wafer-shaped optical apparatus according to the present invention, in the hole forming step, a light shielding film is patterned and formed by aligning the light shielding film with a position of the hole, and the hole is formed using etching processing, using the light shielding film as a mask.

Still preferably, in a method for manufacturing a wafer-shaped optical apparatus according to the present invention, in the pressing step, at least the optical element section is molded while the base material substrate is raised and supported above the lower metal mold.

Still preferably, in a method for manufacturing a wafer-shaped optical apparatus according to the present invention, in the pressing step, a space between the lower metal mold and the upper metal mold is controlled to set a thickness of the optical element and a thickness of a flange section in the periphery of the optical element.

Still preferably, in a method for manufacturing a wafer-shaped optical apparatus according to the present invention, in the resin curing step, the lower metal mold and the upper metal mold are transparent molds, and light is emitted from at least either of an upper surface or a lower surface of the transparent molds to cure the resin.

Still preferably, in a method for manufacturing a wafer-shaped optical apparatus according to the present invention, in the resin curing step, the base material substrate is a glass substrate, and light is emitted from an end surface side of the glass substrate to cure the resin.

Still preferably, in a method for manufacturing a wafer-shaped optical apparatus according to the present invention, in the resin curing step, while the lower metal mold and the upper metal mold are rotated, light is emitted to cure the resin.

An electronic element wafer module according to the present invention includes: an electronic element wafer including, arranged therein, a plurality of electronic elements each with through electrodes; a resin adhesive layer formed in a predetermined region on the electronic element wafer; a transparent cover member covering the electronic element wafer and fixed on the resin adhesive layer; and one or a plurality of layered wafer-shaped optical apparatuses according to the present invention adhered and fixed on the transparent cover member in such a manner to correspond to the plurality of electronic elements respectively, thereby achieving the objective described above.

Preferably, in an electronic element wafer module according to the present invention, the electronic element is an image capturing element having a plurality of light receiving sections for performing a photoelectric conversion on and capturing an image of image light from a subject.

Still preferably, in an electronic element wafer module according to the present invention, the electronic element includes a light emitting element for generating output light and a light receiving element for receiving incident light.

An electronic element module according to the present invention is provided, which is obtained by cutting the electronic element wafer module according to the present invention for each one or plurality of the electronic element modules, thereby achieving the objective described above.

A sensor wafer module according to the present invention includes: a sensor wafer including, arranged therein, a plurality of sensor chip sections with through electrodes; a resin adhesive layer formed in a predetermined region on the sensor wafer; a transparent cover member covering the sensor wafer and fixed on the resin adhesive layer; and one or a plurality of lens modules, as the wafer-shaped optical apparatus according to the present invention, mounted on the transparent cover member to be adhered and fixed thereon in such a manner to correspond to a plurality of image capturing elements respectively, where each of the plurality of sensor chip sections includes therein an image capturing element having a plurality of light receiving sections for performing a photoelectric conversion on and capturing an image of image light from a subject, thereby achieving the objective described above.

A sensor module according to the present invention is provided, which is obtained by cutting the sensor wafer module according to the present invention for each one or plurality of the sensor modules, thereby achieving the objective described above.

An electronic information device according to the present invention is provided, which includes an electronic element module, as a sensor module, used in an image capturing section thereof, the electronic element module being cut from the electronic element wafer module according to the present invention, thereby achieving the objective described above.

An electronic information device according to the present invention is provided, which includes an electronic element module used in an information recording and reproducing section thereof, the electronic element module being cut from the electronic element wafer module according to the present invention, thereby achieving the objective described above.

The functions of the present invention having the structures described above will be described hereinafter.

In the present invention, provided are a base material substrate provided with one or a plurality of holes; a resin optical element section provided in each hole of the base material substrate; and a peripheral flange section provided in a peripheral position of the optical element section on the base material substrate.

Therefore, by using a base material such as glass, contraction of an overall resin does not influence on optical parts such as a resin lens. Such a base material is not used in the optical parts such as a resin lens, but a single optical resin material is used so as to obtain high optical accuracy.

According to the present invention as described above, a glass substrate with holes is used as a base material, so that contraction of resin can be inhibited during the manufacturing and a wafer-shaped lens module can be formed with high accuracy. Further, the variation in thickness of the glass substrate is absorbed by the lens resin formed on the glass substrate, so that the thickness of the lens flange portion can be controlled accurately and the variation between lenses can also be controlled accurately when the lenses are layered. Further, the lens portion is made with a resin only, so that the refractive index can be maintained even, the designing can be facilitated, and the lens thickness can be controlled accurately to obtain a lens with high optical accuracy.

### BRIEF DESCRIPTION OF THE DRAWINGS

FIG. 1 is a partial longitudinal cross sectional view schematically illustrating an exemplary essential structure of a lens module according to Embodiment 1 of the present invention.

FIG. 2 is a perspective view schematically illustrating a glass substrate in FIG. 1.

FIG. 3 is a partial cross sectional view schematically illustrating an exemplary essential part structure of a lower metal mold for molding the lens module in FIG. 1.

FIG. 4 is a partial cross sectional view schematically illustrating a state of the lower metal molding in FIG. 3 being applied with lens resin.

FIG. 5 is a partial cross sectional view schematically illustrating a state of lens resin in FIG. 4 with a glass substrate mounted thereon.

FIG. 6 is a partial cross sectional view schematically illustrating a state of the glass substrate in FIG. 5 with lens resin dispensed on the center part thereof.

FIG. 7 is a partial cross sectional view schematically illustrating a state of the lens resin and glass substrate in FIG. 6 being pressed by lower and upper metal molds.

FIG. 8 is a partial cross sectional view schematically illustrating a state where end surfaces of the glass substrate are supported and fixed at the pressing in FIG. 7.

FIG. 9 is a partial cross sectional view schematically illustrating a state of the lens resin between the lower and upper metal molds in FIG. 7 being cured by ultraviolet rays.

FIG. 10 is a partial cross sectional view schematically illustrating a state of the lens module in FIG. 1 removed from the lower and upper metal molds.

FIG. 11 is a partial cross sectional view of a lens module, schematically illustrating a state where a lens flange section is thicker than the lens module in FIG. 1.

FIG. 12 is a partial cross sectional view of a lens module, schematically illustrating another exemplary variation of the lens module in FIG. 1.

FIG. 13 is a partial cross sectional view of a lens module, schematically illustrating still another exemplary variation of the lens module in FIG. 1.

FIG. 14 is a diagram schematically illustrating a cross sectional structure of a prism module according to the present invention.

FIG. 15 is a diagram schematically illustrating a cross sectional structure of a hologram element.

FIG. 16 is a longitudinal cross sectional view illustrating an exemplary essential part structure of a sensor module according to Embodiment 2 of the present invention.

FIG. 17 is a block diagram illustrating an exemplary diagrammatic structure of an electronic information device according to Embodiment 3 of the present invention, including a sensor module according to Embodiment 2 of the present invention used in an image capturing section thereof.

FIG. 18 is a block diagram illustrating an exemplary diagrammatic structure of an electronic information device as a variation of Embodiment 3 of the present invention, including an electronic element module as a variation of Embodiment 2 of the present invention used in an information recording and reproducing section thereof.

FIG. 19 is a cross sectional view schematically illustrating an example of a conventional lens module disclosed in Reference 1.

FIG. 20 is a cross sectional view schematically illustrating another example of the conventional lens module disclosed in Reference 1.

1 glass substrate

11 hole

12 chromium plating

12a base layer (low reflection chromium plating)

2 resin lens

22a, 22b lens resin material

21 lower metal mold

23 upper metal mold

3 peripheral resin section

4, 4A, 4B lens flange section

5 holder (glass substrate support member)

10, 10A, 10B, 10C lens module

d mold space

30 prism module

31 prism

41 hologram element

50 sensor module

50A electronic element module

51 through wafer

51a image capturing element

51b through hole

52 resin adhesive layer

53 glass plate

54, 541 to 543 lens plate

55, 56 lens adhesive layer

57 light shielding member

90, 90A electronic information device

91 solid-state image capturing apparatus

91A information recording and reproducing section

92, 92A memory section

93, 93A display section

94, 94A communication section

95, 95A image output section

### BEST MODE FOR CARRYING OUT THE INVENTION

Hereinafter, cases will be described in detail with reference to the accompanying figures, as Embodiment 1 with a lens module as a wafer-shaped optical apparatus according to the present invention, and a method for manufacturing the wafer-shaped optical apparatus; as Embodiment 2 where an electronic element wafer module using the lens module as the wafer-shaped optical apparatus is applied to a sensor wafer module; and as Embodiment 3 with an electronic information device, such as a camera equipped cell phone device, including a sensor module as an image input device in an image capturing section thereof, the sensor module being obtained by simultaneously cutting the sensor wafer module.

### Embodiment 1

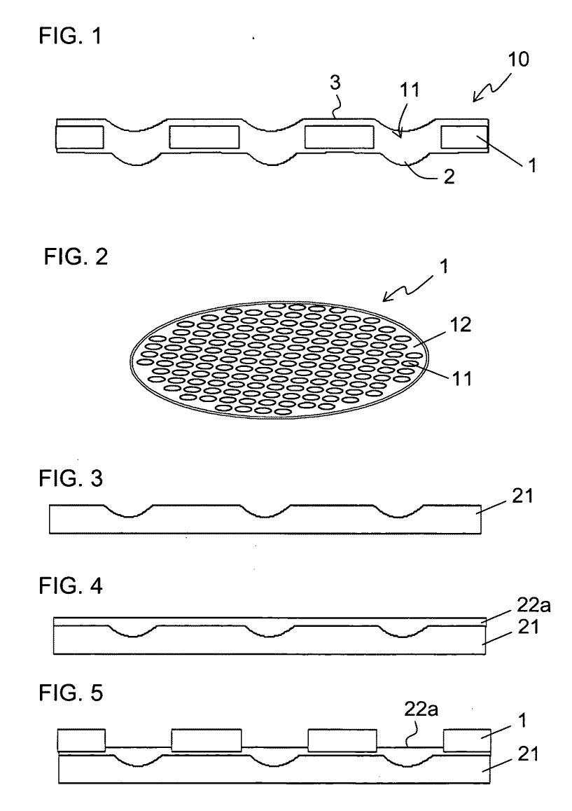

FIG. 1 is a partial longitudinal cross sectional view schematically illustrating an exemplary essential structure of a lens module according to Embodiment 1 of the present invention.

In FIG. 1, a lens module 10 functions as a wafer-shaped optical apparatus according to Embodiment 1. The lens module 10 includes: a glass substrate 1 as a base material (framework) with a plurality of holes 11 formed therein; a resin lens 2 formed to correspond to each of the plurality of holes 11; and a peripheral resin section 3 made with the same resin material as the resin lens 2 and formed on upper and lower surfaces of the glass substrate 1 in the periphery of the resin lens 2.

As illustrated in FIG. 2, the glass substrate 1 is a thin disk in shape with a light shielding chromium plating 12 provided on a front surface side thereof. The glass substrate 1 further includes a plurality of holes 11 formed therein in a matrix at equal intervals. The glass substrate 1 has an effect of inhibiting overall contraction of the resin lens 2. As illustrated in FIG. 13, the chromium plating 12 functions as a reflection preventing film on the side close to a base layer 12a (low reflection chromium plating), and prevents a flare by preventing unnecessary reflecting light from returning to the inside. The chromium plating 12 and base layer 12a (low reflection chromium plating) can also be used as a mask for etching processing of the plurality of holes 11.

The resin lens 2 is formed in each of the plurality of holes 11 in the glass substrate 1, with an only single resin material. The refractive index is equally uniform in the resin lens 2, which facilitates the designing. The thickness of the resin lens 2 is determined by the thickness of the resin between metal molds. Since resin molding is possible by machinery, it is possible to restrain the variation in lens thickness down to about 1 μm and obtain the resin lens 2 with high accuracy. In addition, the lens shape of the resin lens 2 can be formed by transferring a metal mold shape, so that a desired non-spherical shape with an accurate focal distance can be formed. In addition, the glass substrate 1 is used as a base material and overall resin contraction does not influence the individual resin lenses 2, which allows to form the non-spherical resin lenses 2 with accurate dimensions and with high optical accuracy.

The peripheral resin section 3 is formed on each of upper and lower surfaces of the glass substrate 1. The peripheral resin section 3 absorbs the variation in thickness of the glass substrate 1, and the total thickness of the peripheral resin section 3 and the glass substrate 1 can be formed with mechanical accuracy between metal molds. Therefore, it is possible to restrain the variation in thickness down to about 1 μm and obtain a lens flange section 4 with high accuracy as an overlapping section in the periphery of the lens.

A method for manufacturing a lens module 10 according to Embodiment 1 with the structure described above will be described.

First, as illustrated in FIG. 3, a lower metal mold 21 of the lens module 10 is prepared. The lower metal mold 21 may be made by processing metal, by processing glass, or by forming a plurality of molds on a glass.

Next, as illustrated in FIG. 4, a lens resin material 22a is applied on the lower metal mold 21 of the lens module 10. The application of the lens resin material 22a can be performed using ordinary methods, such as spin coating or dispensing.

Subsequently, as illustrated in FIG. 5, a glass substrate 1 is aligned and placed on the lens resin material 22a on the lower metal mold 21.

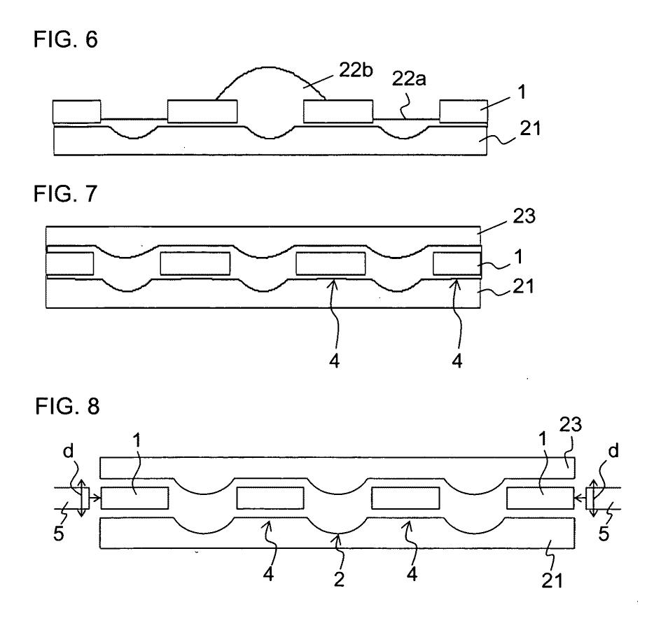

Thereafter, as illustrated in FIG. 6, a lens resin material 22b is applied on a center part of the glass substrate 1. The lens resin material 22b is the same material as the lens resin material 22a. The method for applying the lens resin material 22b can be any method in general, but the lens resin material 22b is dispensed on the center part of the glass substrate 1 in FIG. 6.

Further, as illustrated in FIG. 7, an upper metal mold 23 is positioned (aligned) with the lower metal mold 21 to press the glass substrate 1 and the lens resin materials 22a and 22b from top and bottom by the lower metal mold 21 and the upper metal mold 23. As a result, the lens resin material 22b can be spread out evenly on the entire surface. At this stage, the space between the upper metal mold 23 and the lower metal mold 21 is mechanically controlled in an accurate manner (i.e., a mold space d is controlled) regardless of the thickness of the glass substrate 1 while the glass substrate 1 is held from both sides by a holder 5 as illustrated in FIG. 8, so that it becomes possible to restrain the variation in the overall thickness of the lens module 10 down to about 1 μm. Thereby, it becomes possible to control the thickness of the portion of the lens flange section 4 evenly, which is in the periphery of the resin lens 2 including the lens resin and the glass substrate 1. As a result, the resin lens 2 can be manufactured with highly accurate dimensions.

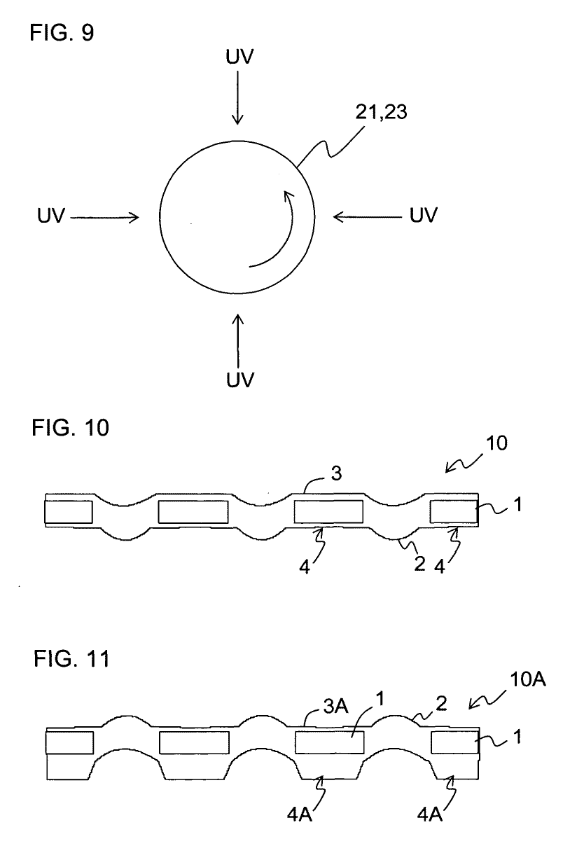

Thereafter, the resin material of the resin lens 2 is cured by light or heat. In this case, as illustrated in FIG. 9, the lower metal mold 21 and the upper metal mold 23 can be rotated while ultraviolet rays UV, for example, are irradiated evenly on an end surface of the glass substrate 1 from, for example, four directions orthogonal to one another on a plane surface relative to the thickness portion of the glass substrate 1 stuck between the lower metal mold 21 and the upper metal mold 23 in a planar view. As a result, the ultraviolet rays UV transmit through the glass substrate 1 to cure the resin lens 2 efficiently, which is positioned in each of the holes 11 in the glass substrate 1. For the portion of the resin lens 2 corresponding to each hole 11 of the glass substrate 1 and the peripheral resin section 3 on top and bottom of the glass substrate 1, corresponding to the portion of the lens flange section 4, when the portion of the resin lens 2 is cured, the position of the thin peripheral resin section 3 is not changed since it is fixed to the top and bottom of the glass substrate 1 and the portion of the resin lens 2 only is cured. Therefore, the overall resin contraction in the lens module 10 is prevented by the glass substrate 1, so that each resin lens 2 will not be harmfully influenced. Thus, high dimensional accuracy can be obtained in the resin lens 2, with a single resin material. Only the portion of the resin lens 2 corresponding to each hole 11 of the glass substrate 1 contracts during the resin curing. It is also possible to prepare transparent lower and upper molds as the lower metal mold 21 and the upper metal mold 23 and irradiate ultraviolet rays UV, for example, onto the upper and lower surfaces thereof, so that the lens resin material can be cured simultaneously in an efficient and even manner.

Subsequently, the lower metal mold 21 and the upper metal mold 23 are removed, and each resin lens 2 is formed by corresponding to each of the plurality of holes 11, as illustrated in FIG. 10. Further, it is possible to form the peripheral resin section 3 with the same resin material on the glass substrate 1 in the periphery of the resin lens 2.

Besides, the space between the upper metal mold 23 and the lower metal mold 21 can be set even wider and the shape of the metal molds can be changed, so that a lens module 10A can be formed as illustrated in FIG. 11, which lens module includes a thick lens flange section 4A as a lens periphery including the lens resin and the glass substrate 1. As described above, the shape of the lens flange section 4A in the lens periphery can be changed without restraint while the overall thickness of the lens module 10A is maintained even.

According to Embodiment 1 as described above, the glass substrate 1 with the plurality of holes 11 is used as a base material (framework), and therefore the overall resin contraction occurred during the manufacturing is restrained and the wafer-shaped lens module 10 or 10A having a plurality of resin lenses with high dimensional accuracy can be formed. Further, the variation in the thickness of the glass substrate 1 is absorbed by the lens resin formed on the glass substrate 1, and therefore the thickness of the flange section 4 or 4A can be controlled accurately and the variation between the resin lenses 2 can also be controlled accurately when they are layered. Further, the lens portion of the resin lens 2 is made only of a single lens resin, and therefore the refractive index can be maintained even, the designing can be facilitated, and the thickness can be controlled accurately to manufacture a condensing lens with high accuracy. Further, the hard glass substrate 1 is used as a framework in the lens flange section 4 or 4A of the resin lens 2, and therefore the wafer-shaped lens module 10 or 10A maintains its own shape, which makes it easy to be handled.

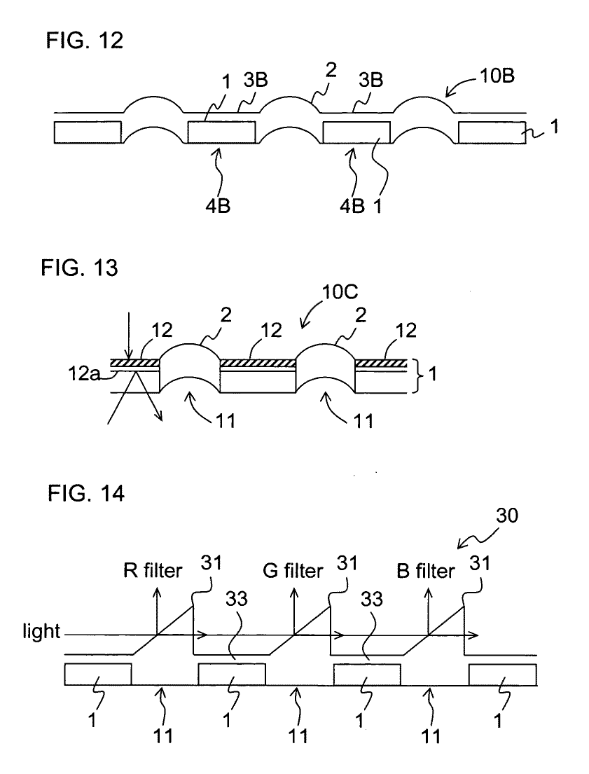

In Embodiment 1, as illustrated in FIG. 8, the glass substrate 1 is held by the holder 5 and the resin material of the resin lenses 2 is positioned on the upper and lower positions of the glass substrate 1 while the glass substrate 1 is raised above the lower metal mold 21. However, the embodiment is not limited to this. The glass substrate 1 can be directly mounted on the lower metal mold 21, and the lens resin material 22b is dispensed on the center part of the glass substrate 1. The lens resin material 22b is next aligned by the upper and lower metal molds, is pressed and cured. Subsequently, the molds are removed to take out a lens module 10B illustrated in FIG. 12. At the lens flange section 4B in the periphery of the lens of the lens module 10B, the lens resin does not reach the lower surface side of the glass substrate 1, but the lens resin exists only on the upper surface side of the glass substrate 1, to configure a peripheral resin section 3B. In addition, as illustrated in a lens module 10C in FIG. 13, a resin lens 2 is provided in each hole 11 of a glass substrate 1. No lens resin reaches an upper or lower surface side of the glass substrate 1, and there is no peripheral resin section 3. In this case, it is not necessary to control the thickness (space) by metal molds, and it is only necessary to press an upper metal mold 23 onto the glass substrate 1 above a lower metal mold 21. In terms of the functionality of a metal mold apparatus, this operation is readily achieved and the lens module 10C can be mass-produced. Since the thickness of the glass substrate 1 is not even (there is about 5% variation in the thickness between substrates; for example, there is a variation of 10 μm with a substrate of 200 μm in thickness), the thickness controlling (space controlling) by the metal molds has better dimensional accuracy (with error of about 1 μm). Further, it is better to include the peripheral resin section 3 because the unevenness is absorbed from the thickness in the glass substrate 1.

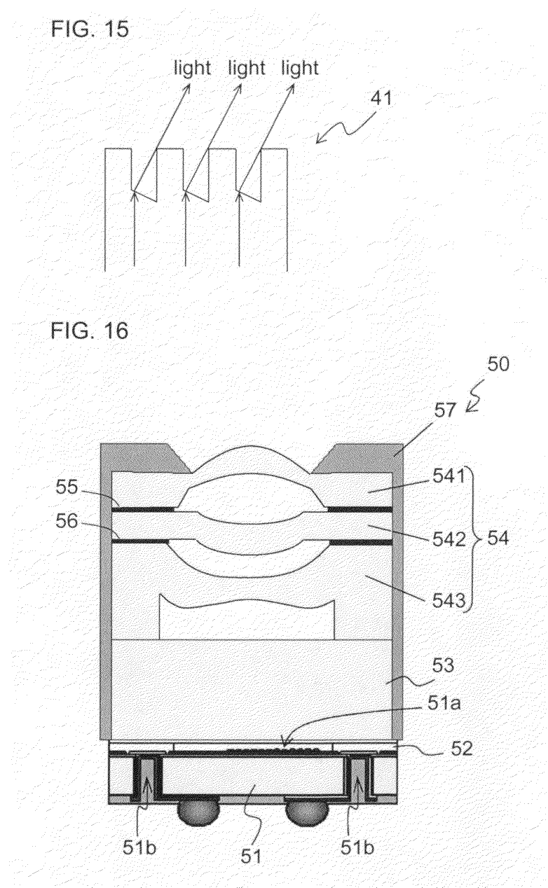

Also in Embodiment 1, the lens modules 10, 10A, 10B and 10C have been described as a wafer-shaped optical apparatus; however, without the limitation to this, the wafer-shaped optical apparatus may be a plurality of reflection plates, a plurality of waveguides, or a plurality of hologram elements for refracting incident light or output light in a predetermined direction. For example, in a case of a plurality of reflection plates, a prism module 30, as a wafer-shaped optical apparatus illustrated in FIG. 14, can be manufactured by replacing the resin lens 2 in Embodiment 1 with a prism 31 to manufacture metal molds. In this case, as similar to the case in Embodiment 1 described above, the prism 31 formed corresponding to each of a plurality of holes 11 in a glass substrate 1, and a peripheral resin section 33 formed on the glass substrate 1 in the periphery of the prism 31 with the same material as the prism 31, are included. It is also possible to provide filters of three primary colors RGB (Red, Green and Blue) in a reflecting direction of each prism 31 to configure a color monitor. Further, instead of the prism 31, it is also possible to provide a hologram element 41, as illustrated in FIG. 15.

Hereinafter, as Embodiment 2 with an electronic element module simultaneously cut and manufactured from an electronic element wafer module according to the present invention, a case will be described in detail with reference to FIG. 16, where the electronic element module is applied to a sensor module simultaneously manufactured by cutting a sensor wafer module. In the sensor wafer module, a plurality of image capturing elements and one or a plurality of lens modules (which may include any of the lens module 10, 10A, 10B or 10C in Embodiment 1 described above) for forming an image of incident light on the image capturing element are modularized (integrated), the image capturing element having a plurality of light receiving sections for performing a photoelectric conversion on and capturing an image of image light from a subject.

### Embodiment 2

FIG. 16 is a longitudinal cross sectional view illustrating an exemplary essential structure of a sensor module according to Embodiment 2 of the present invention.

In FIG. 16, a sensor module 50 according to Embodiment 2 includes: a through wafer 51 provided with an image capturing element 51a and a through hole 51b connecting a front surface and a back surface thereof, the image capturing element 51a including a plurality of light receiving sections, that is, photoelectric conversion sections (photodiodes) corresponding to a plurality of pixels, provided on the front surface thereof, as an electronic element; a resin adhesive layer 52 formed around the image capturing element 51a of the through wafer 51; a glass plate 53 as a cover glass covering the resin adhesive layer 52; a lens plate 54 provided on the glass plate 53 and in which a plurality of lens plates 541 to 543 are layered as optical elements for focusing incident light on the image capturing element 51a; lens adhesive layers 55 and 56 for adhering and fixing the lens plates 541 to 543; and a light shielding member 57 which is opened as a circular light receiving aperture at the center part of the upper most lens plate 541 among the lens plates 541 to 543 and which shields light at the rest of the front surface portion and the side surface portion of the lens plates 541 to 543 and the glass plate 53. Above the through wafer 51, the glass plate 53 and lens plate 54 are aligned in this order and adhered top and bottom by the resin adhesive layer 52 and lens adhesive layers 55 and 56. The sensor module 50 according to Embodiment 2 is individually manufactured by cutting a wafer-level sensor wafer module and subsequently attaching the light shielding member 57 from the top. The sensor wafer module includes: the through wafer 51; the resin adhesive layer 52; the glass plate 53; the plurality of lens plates 541 to 543 (which may also be simultaneously cut from any of the lens module 10, 10A, 10B or 10C in Embodiment 1 described above); and the lens adhesive layers 55 and 56, all of which are layered in the sensor wafer module.

With regard to the sensor wafer module, a plurality of image capturing elements 51a (where a plurality of light receiving sections are provided constituting a plurality of pixels for each of the image capturing elements) are arranged in a matrix on a front surface side of a sensor wafer on which a plurality of through wafers 51 before being cut are provided; the thickness of the through wafer 51 is between 100 μm and 200 μm; and a plurality of through holes 51b are provided, penetrating from the back surface to below a pad on the front surface thereof. The side wall and back surface side of the through hole 51b are covered with an insulation film, and a wiring layer is formed through the through hole 51b to the back surface, contacting with the pad. A solder resist is formed on the wiring layer and the back surface. The solder resist is opened at a portion where a solder ball is formed on the wiring layer, and the solder ball is formed there exposed to the outside. Each of the layers can be formed by various techniques, such as photolithography, etching, gilding, and a CVD method, used in an ordinary semiconductor process. After the wafer cutting, a sensor substrate (a sensor chip section as an electronic element chip section) having an element region at the center part thereof is configured as the through wafer 51.

The resin adhesive layer 52 is formed at a predetermined position on the through wafer 51, using an ordinary photolithography technique, and the glass plate 53 is adhered thereon. Other than the photolithography technique, a screen printing method or dispensing method can be used for the forming. The resin adhesive layer 52 includes a shallow groove (air pass) formed on a part of the surface to which the glass plate 53 is fixed. This groove can be formed by a photolithography technique at the same time when the resin adhesive layer 52 is formed. The thickness of the resin is between 30 μm and 300 μm, and the depth of the groove is about between 3 μm and 20 μm. The groove is for preventing condensation from being formed when an internal space of a sensor region, in which the image capturing element 51a is provided as an electronic element on the through wafer 51, is sealed in the case where the top of the semiconductor surface is covered by the glass plate 53. The groove is structured to include a collecting space region therebetween for making it difficult for cutting water, slurry or the like to enter the internal space of the sensor region and adhere to the surface of the sensor later during the dicing into individual modules. The groove (air pass) for making the space region into a semi-sealed state, is formed in a diagonal straight line, an S shape, a maze-like shape (herein, the groove is a diagonal straight line), or a combination thereof, to provide some distance therein.

Further, the resin adhesive layer 52 herein includes, formed therein, not only the groove for continuously connecting the space region above each of the plurality of image capturing elements 51a with the outside, but also a groove for further continuously connecting with the outside through another space region, which is continuously connected with the previous space region and groove. In addition, the resin adhesive layer 52 is provided for each image capturing element 51a, and is provided on the region except the region of the image capturing element 51a as well as on the region except a dicing region between adjacent image capturing elements 51a. Without the limitation to such a groove of the resin adhesive layer 52, a different air pass may be provided. Alternatively, the resin adhesive layer 52 may have a structure with a material capable of continuously connecting with the inside (where the particles of the material are coarse, or moisture can pass from the inside of the material to the outside).

The lens plate 54 is a transparent resin lens plate, and may include any of simultaneously cut lens module 10, 10a, 10B or 10C according to Embodiment 1 described above, and has a structure similar to that of the case in Embodiment 1 described above. The lens plate 54 is constituted of: a lens region (corresponding to the resin lens 2) with a lens function; and a peripheral lens flange section (corresponding to the lens flange section 4) functioning as a spacer section with a spacer function. The overall lens plate 54 is made of the same resin material. The method for forming the lens plate 54 is as follows: lens resin materials 22a and 22b are inserted into an upper mold 23 and a lower mold 21 with a glass substrate 1 as a base material; a distance between the upper mold 23 and the lower mold 21 is controlled accurately to obtain a predetermined thickness; the lens resin is cured using a method such as ultraviolet ray (UV) curing, heat curing or the like; and a heat treatment is further performed to reduce the internal stress and stabilize the lens shape. As a result, the resin lens plates 541 to 543 can be formed with a predetermined lens shape and a predetermined lens thickness.

As previously described, the upper mold 23 and the lower mold 21 may be made of glass or metal. In Embodiment 2, three of the formed lens plates 541 to 543 are structured as being layered at the respective lens flange sections. The adhesive layers 55 and 56 are used for the layering, and the adhesive layers 55 and 56 may have a light shielding function.

The lens plate 54 is constituted of a plurality of lens plates as an optical element, which are an aberration correction lens 543, a diffusion lens 542 and a condensing lens 541 (or a condensing lens in a case of one lens). The lens plate 54 includes a lens region at the center part, and is provided with a lens flange section as a peripheral portion, which is a spacer section with a predetermined thickness on the outer circumference side of the lens region. Such spacer sections have a predetermined thickness and are provided on the outer circumference side of the lens plate 54. The spacer sections are layered and placed in said order from the bottom. The spacer sections have a positioning function, and the positioning function is enabled by tapered concave and convex port ions or an alignment mark. The adhesive layer 55 and/or adhesive layer 56 for adhering the three-lens lens plate 54 may also have a light shielding function, and the adhesive layers 55 and 56 may contain a solid-body for determining a space.

In Embodiment 2, as an electronic element, the case of the image capturing element has been described, where the image capturing element includes the plurality of light receiving sections for performing a photoelectric conversion on and capturing an image of image light from a subject. However, without the limitation to this, the electronic element may include a light emitting element for emitting output light and a light receiving element for receiving incident light. In this case, an optical element section may be a hologram element for refracting the output and/or incident light in a predetermined direction. A plurality of hologram elements at a wafer level can be manufactured in a similar manner for the wafer-shaped optical apparatus according to Embodiment 1 described above. An electronic element wafer module in this case includes: an electronic element wafer formed by arranging a plurality of electronic elements each with through electrodes; a resin adhesive layer formed in a predetermined region on the electronic element wafer; a transparent cover member covering the electronic element wafer and fixed on the resin adhesive layer; and one or a plurality of layered wafer-shaped optical apparatuses adhered and fixed on the transparent cover member in such a manner to correspond to a plurality of electronic elements respectively. Each electronic element module is obtained by cutting and individualizing the electronic element wafer module. Therefore, the difference from the case in FIG. 16 is that the light emitting element and light receiving element are included instead of the image capturing element 51a in FIG. 16, and the hologram element is provided instead of the lens plate 54 in FIG. 16.

Next, as Embodiment 3 with a finished product with the electronic element module, an electronic information device including the sensor module according to Embodiment 2 used in an image capturing section, and an electronic information device including the electronic element module used in an information recording and reproducing section as an exemplary variation of Embodiment 2, will be described in detail with reference to the attached figures.

### Embodiment 3

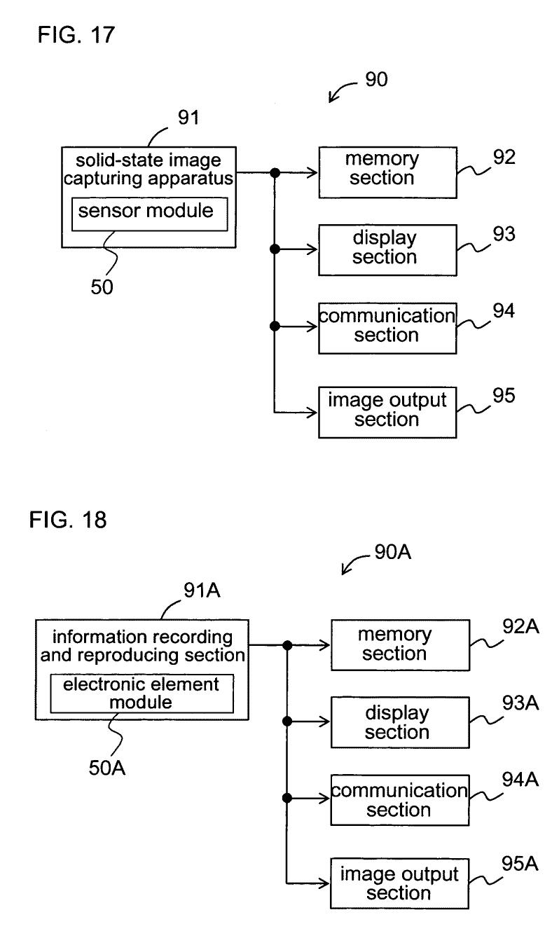

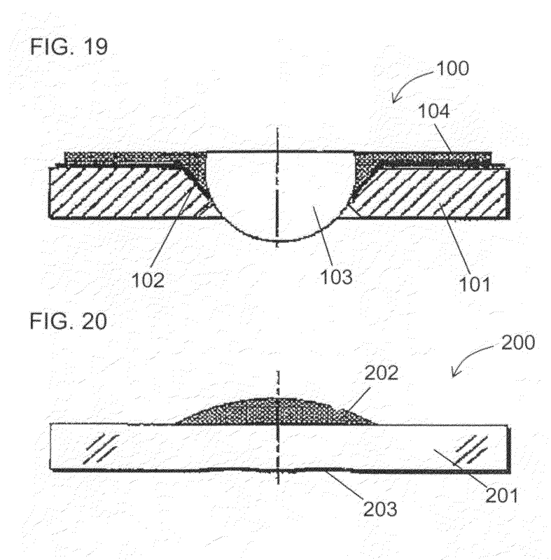

FIG. 17 is a block diagram illustrating an exemplary diagrammatic structure of an electronic information device according to Embodiment 3 of the present invention, including a sensor module 50 according to Embodiment 2 of the present invention used in an image capturing section thereof.

In FIG. 17, an electronic information device 90 according to Embodiment 3 of the present invention includes: a solid-state image capturing apparatus 91 for performing various signal processing on an image capturing signal from the sensor module 50 according to Embodiment 2 so as to obtain a color image signal; a memory section 92 (e.g., recording media) for data-recording a color image signal from the solid-state image capturing apparatus 91 after predetermined signal processing is performed on the color image signal for recording; a display section 93 (e.g., a liquid crystal display apparatus) for displaying the color image signal from the solid-state image capturing apparatus 91 on a display screen (e.g., liquid crystal display screen) after predetermined signal processing is performed on the color image signal for display; a communication section 94 (e.g., a transmitting and receiving device) for communicating the color image signal from the solid-state image capturing apparatus 91 after predetermined signal processing is performed on the color image signal for communication; and an image output section 95 (e.g., a printer) for printing the color image signal from the solid-state image capturing apparatus 91 after predetermined signal processing is performed for printing. Without any limitations to this, the electronic information device 90 may include at least any of the memory section 92, the display section 93, the communication section 94, and the image output section 95 such as a printer, other than the solid-state image capturing apparatus 91.

As the electronic information device 90, an electronic device which includes an image input device is conceivable, such as a digital camera (e.g., digital video camera or digital still camera), an image input camera (e.g., a monitoring camera, a door phone camera, a camera equipped in a vehicle including a vehicle back view monitoring camera, or a television telephone camera), a scanner, a facsimile machine, a television telephone device, a camera-equipped cell phone device and a portable digital assistant (PDA), as previously described.

Therefore, according to Embodiment 3 of the present invention, the color image signal from the solid-state image capturing apparatus 91 can be: displayed on a display screen properly; printed out on a sheet of paper using the image output section 95; communicated properly as communication data via a wire or a radio; stored properly at the memory section 92 by performing predetermined data compression processing; and further various data processes can be properly performed.

Without the limitation to the electronic information device 90 according to Embodiment 3, the electronic information device maybe a pick up apparatus or an information recording and reproducing apparatus, including the electronic element module (e.g., a light emitting element and light receiving element module) of the present invention used in an information recording and reproducing section thereof. In this case, an optical element of the pick up apparatus or information recording and reproducing apparatus is an optical function element (e.g., a hologram optical element) that directs output light straight to be output and refracting and guiding incident light in a predetermined direction. In addition, as an electronic element of the pick up apparatus or information recording and reproducing apparatus, a light emitting element (e.g., a semiconductor laser element or a laser chip) for emitting output light and a light receiving element (e.g., a photo IC) for receiving incident light are included.

As similar to the case in FIG. 17, and for example, as illustrated in FIG. 18, an electronic information device 90A, including an electronic element module (e.g., a light emitting element and light receiving element module) used in an information recording and reproducing section thereof, includes: an information recording and reproducing section 91A for performing various signal processing on a data signal from an electronic element module 50A, which is the light emitting element and light receiving element module described above, so as to obtain a predetermined data signal; a memory section 92A (e.g., recording media) for data-recording a data signal from the information recording and reproducing section 91A after predetermined signal processing is performed on the predetermined data signal for recording; a display section 93A (e.g., a liquid crystal display apparatus) for displaying the predetermined data signal from the information recording and reproducing section 91A on a display screen (e.g., liquid crystal display screen) after predetermined signal processing is performed on the data signal for display; a communication section 94A (e.g., a transmitting and receiving device) for communicating the predetermined data signal from the information recording and reproducing section 91A after predetermined signal processing is performed on the data signal for communication; and an image output section 95A (e.g., a printer) for printing the data signal from the information recording and reproducing section 91A after predetermined signal processing is performed for printing. Without any limitations to this, the electronic information device 90A may include at least any of the memory section 92A, the display section 93A, the communication section 94A, and the image output section 95A such as a printer, other than the information recording and reproducing section 91A.

Although not particularly described in detail in Embodiment 1, included are: a base material substrate (glass substrate 1) provided with one or a plurality of holes; a resin optical element section (resin lens 2) provided in each hole 11 in the base material substrate; and a lens flange section 4 provided at a base material substrate position in the periphery of an optical element section. As a result, by using a base material such as the glass substrate 1, contraction of the overall resin does not influence on optical parts such as the resin lens 2. Such a base material is not used as a framework in the optical parts such as the resin lens 2, but a single optical resin material is used so as to obtain high optical accuracy.

As described above, the present invention is exemplified by the use of its preferred Embodiments 1 to 3. However, the present invention should not be interpreted solely based on Embodiments 1 to 3 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 3 of the present invention. Furthermore, it is understood that any patent, any patent application and any references cited in the present specification should be incorporated by reference in the present specification in the same manner as the contents are specifically described therein.

### INDUSTRIAL APPLICABILITY

The present invention can be applied in the field of: a wafer-shaped optical apparatus comprised of a plurality of lenses for focusing incident light, or a plurality of optical functional elements for directing and reflecting straight output light and refracting and guiding incident light in a predetermined direction, and a method for manufacturing the wafer-shaped optical apparatus; an electronic element wafer module including a plurality of image capturing elements modularized (integrated) therein, the image capturing elements having a plurality of light receiving sections for performing a photoelectric conversion on and capturing an image of image light from a subject, corresponding to respective lenses, or an electronic element wafer module including a plurality of light emitting elements for generating output light and light receiving elements for receiving incident light, corresponding to respective optical functional elements, modularized (integrated) therein; an electronic element module manufactured by simultaneously cutting the electronic element wafer module; a sensor wafer module including a plurality of image capturing elements having a plurality of light receiving sections for performing a photoelectric conversion on and capturing an image of image light from a subject, and lenses for forming an image from incident light on the image capturing elements, modularized (integrated) therein; and an electronic information device, such as a digital camera (e.g., a digital video camera or a digital still camera), an image input camera (e.g., a car-mounted camera), a scanner, a facsimile machine, a television telephone device, a camera-equipped cell phone device and a personal digital assistant (PDA), the electronic information device including a sensor module cut from the sensor wafer module as an image input device, such as a car-mounted camera, used in an image capturing section of the electronic information device, or an electronic information device, such as a pick-up apparatus, including the electronic element module in an information recording and reproducing section thereof. According to the present invention, a glass substrate with holes is used as a base material, so that contraction of resin can be inhibited during the manufacturing and a wafer-shaped lens module can be formed with high accuracy. Further, the variation in thickness of the glass substrate is absorbed by the lens resin formed on the glass substrate, so that the thickness of the lens flange portion can be controlled accurately and the variation between lenses can also be controlled accurately when the lenses are layered. Further, the lens portion is made with a resin only, so that the refractive index can be maintained even, the designing can be facilitated, and the lens thickness can be controlled accurately to obtain a lens with high optical accuracy.

1. A wafer-shaped optical apparatus, comprising:
a base material substrate with one or a plurality of holes provided therein;
a resin optical element section provided in each hole of the base material substrate; and
a flange section provided in a peripheral position of the optical element section on the base material substrate.

2. A wafer-shaped optical apparatus according to claim 1, wherein the base material substrate is a glass substrate.

3. A wafer-shaped optical apparatus according to claim 1, wherein a light shielding film is provided on a surface of the base material substrate.

4. A wafer-shaped optical apparatus according to claim 3, wherein the light shielding film has a two layered structure of a light shielding chromium plating and a low reflection chromium plating as a base layer of the light shielding chromium plating.

5. A wafer-shaped optical apparatus according to claim 1, wherein the optical element section is any of a lens, a mirror optical element, a waveguide section, a prism or a hologram element.

6. A wafer-shaped optical apparatus according to claim 1, wherein the flange section is constituted of at least the base material substrate among the base material substrate and a resin material identical to the optical element section.

7. A wafer-shaped optical apparatus according to claim 1 or 6, wherein in the flange section, a resin material identical to that of the optical element section is arranged in a film shape on at least one of an upper surface and a lower surface of the base material substrate.

8. A wafer-shaped optical apparatus according to claim 1 or 6, wherein the flange section is constituted of only the base material substrate.

9. A wafer-shaped optical apparatus according to claim 1, wherein the hole is in any shape of a circle, an ellipse, a rectangle, or a polygon.

10. A wafer-shaped optical apparatus according to claim 1, wherein a resin material of the optical element section is a thermosetting resin material or a photo-curable resin.

11. A method for manufacturing a wafer-shaped optical apparatus with a base material substrate as a framework and a resin optical element section being molded at a hole of the base material substrate, the method comprising:
a hole forming step of forming one or a plurality of holes in the base material substrate;
a pressing step of putting an optical element resin and the base material substrate between optical element lower and upper metal molds formed to correspond to the hole, to mold at least the optical element section; and
a resin curing step of curing the resin using heat or light.

12. A method for manufacturing a wafer-shaped optical apparatus according to claim 11, wherein in the hole forming step, a light shielding film is patterned and formed by aligning the light shielding film with a position of the hole, and the hole is formed using etching processing, using the light shielding film as a mask.

13. A method for manufacturing a wafer-shaped optical apparatus according to claim 11, wherein in the pressing step, at least the optical element section is molded while the base material substrate is raised and supported above the lower metal mold.

14. A method for manufacturing a wafer-shaped optical apparatus according to claim 11, wherein in the pressing step, a space between the lower metal mold and the upper metal mold is controlled to set a thickness of the optical element and a thickness of a flange section in the periphery of the optical element.

15. A method for manufacturing a wafer-shaped optical apparatus according to claim 11, wherein in the resin curing step, the lower metal mold and the upper metal mold are transparent molds, and light is emitted from at least either of an upper surface or a lower surface of the transparent molds to cure the resin.

16. A method for manufacturing a wafer-shaped optical apparatus according to claim 11, wherein in the resin curing step, the base material substrate is a glass substrate, and light is emitted from an end surface side of the glass substrate to cure the resin.

17. A method for manufacturing a wafer-shaped optical apparatus according to claim 11, wherein in the resin curing step, while the lower metal mold and the upper metal mold are rotated, light is emitted to cure the resin.

18. An electronic element wafer module, comprising:
an electronic element wafer including, arranged therein, a plurality of electronic elements each with through electrodes;
a resin adhesive layer formed in a predetermined region on the electronic element wafer;
a transparent cover member covering the electronic element wafer and fixed on the resin adhesive layer; and
one or a plurality of layered wafer-shaped optical apparatuses according to claim 1 adhered and fixed on the transparent cover member in such a manner to correspond to the plurality of electronic elements respectively.

19. An electronic element wafer module according to claim 18, wherein the electronic element is an image capturing element having a plurality of light receiving sections for performing a photoelectric conversion on and capturing an image of image light from a subject.

20. An electronic element wafer module according to claim 18, wherein the electronic element includes a light emitting element for generating output light and a light receiving element for receiving incident light.

21. An electronic element module obtained by cutting the electronic element wafer module according to claim 18 for each one or plurality of the electronic element modules.

22. A sensor wafer module, comprising:
a sensor wafer including, arranged therein, a plurality of sensor chip sections with through electrodes;
a resin adhesive layer formed in a predetermined region on the sensor wafer;
a transparent cover member covering the sensor wafer and fixed on the resin adhesive layer; and
one or a plurality of lens modules, as the wafer-shaped optical apparatus according to claim 1, mounted on the transparent cover member to be adhered and fixed thereon in such a manner to correspond to a plurality of image capturing elements respectively,
wherein each of the plurality of sensor chip sections includes therein an image capturing element having a plurality of light receiving sections for performing a photoelectric conversion on and capturing an image of image light from a subject.

23. A sensor module obtained by cutting the sensor wafer module according to claim 22 for each one or plurality of the sensor modules.

24. An electronic information device including an electronic element module, as a sensor module, used in an image capturing section thereof, the electronic element module being cut from the electronic element wafer module according to claim 19.

25. An electronic information device including an electronic element module used in an information recording and reproducing section thereof, the electronic element module being cut from the electronic element wafer module according to claim 20.
